(19) United States
(12) Patent Application Publication
(10) Pub. No.: US 2017/0170805 A1
(43) Pub. Date: Jun. 15, 2017

(54) DUAL TRENCH DEEP TRENCH BASED UNRELEASED MEMS RESONATORS

(71) Applicants: Wentao Wang, Cambridge, MA (US); Dana Weinstein, Cambridge, MA (US)

(72) Inventors: Wentao Wang, Cambridge, MA (US); Dana Weinstein, Cambridge, MA (US)

(21) Appl. No.: 15/285,223

(22) Filed: Oct. 4, 2016

Related U.S. Application Data
(63) Continuation of application No. PCT/US2016/012794, filed on Jan. 11, 2016.
(60) Provisional application No. 62/150,399, filed on Apr. 21, 2015.

(51) Int. Cl. H03H 9/17; H03H 3/02; H01G 4/06

(52) U.S. Cl. CPC H03H 9/17; H01G 4/06; H03H 3/02; H03H 2009/155

(57) ABSTRACT

A deep trench (DT) MEMS resonator includes a periodic array of unit cells, each of which includes a single DT formed in a semiconductor substrate and filled with a material whose acoustic impedance is different than that of the substrate. The filled DT is used as both an electrical capacitor and a mechanical structure at the same time, making it an elegant design that reduces footprint and fabrication complexity. Adding a second DT to each unit cell in a DT MEMS resonator forms a dual-trench DT (DTDT) MEMS resonator. In a DTDT unit cell, the first DT is filled with a conductor to sense, conduct, and/or generate an acoustic wave. The second DT in the DTDT unit cell is filled with an insulator. The width, filling, etc. of the second DT in the DTDT unit cell can be selected to tune the acoustic passband of the DTDT unit cell.

### CROSS-REFERENCE TO RELATED PATENT APPLICATION

This application is a bypass continuation of International Application No. PCT/US2016/012794, filed on Jan. 11, 2016, and entitled “Dual Trench Deep Trench-Based Unreleased MEMS Resonators,” which in turn claims priority, under 35 U.S.C. §119(e), from U.S. Application No. 62/150,399, filed Apr. 21, 2015, and entitled “Dual Trench Deep Trench based Unreleased Coupled MEMS Resonators.” Each of these applications is hereby incorporated herein by reference in its entirety.

### GOVERNMENT SUPPORT

This invention was made with Government support under Grant No. N66001-13-1-4022 awarded by the Space and Naval Warfare Systems Center and under Grant No. ECCS-1150493 awarded by the National Science Foundation. The Government has certain rights in the invention.

### BACKGROUND

The demand for small, high performance wireless communication devices has pushed research interests towards the design and development of low power, small footprint, and single-chip Complementary Metal-Oxide Semiconductor (CMOS) integrated wireless-transceivers. The potential of Micro Electro Mechanical Systems (MEMS) technology to meet some of these requirements has led to the recent development and adoption of miniaturized, silicon micro-machined mechanical resonators for operation as timing references. These silicon MEMS resonators provide high mechanical quality factors (Q), low static power dissipation, and CMOS manufacturing compatibility, making them attractive alternatives to quartz based timing references.

To be used as a low-power, frequency stable electronic clock, a MEMS resonator should exhibit reduced motional resistance (Rₓ) and increased Q. The motional resistance Rₓof a MEMS resonator can be defined as the series resistance in the Butterworth-Van Dyke (BVD) model, where Rₓ is equal to the driving voltage divided by the sensing current at resonance frequency. The quality factor Q of a MEMS resonator can be defined as 2π times the stored energy divided by the energy dissipated per cycle; equivalently, Q can also be defined as the angular frequency (ω) times the stored energy divided by power loss, or as the resonance peak frequency divided by half power bandwidth (ω/Δω).

Wireless communication devices also rely on high performance bandpass transmission filters, which are used to reject any unwanted incoming RF signals. In some wireless communication applications (e.g., GSM telephony, 3G, LTE, WiFi, etc.), bandpass transmission filters let through only a very narrow portion of the incoming frequency spectrum. To achieve this frequency selectivity, electronics manufacturers, phone manufacturers, and wireless communication developers use Thin-Film Bulk Acoustic Wave Resonators (FBARs) and/or Surface Acoustic Wave (SAW) resonators. Such FBAR/SAW devices are micro-electro-mechanical (MEM) acoustic cavities that can achieve large Q and very low Rₓ values. Neither FBAR nor SAW resonators, however, can be monolithically integrated with other CMOS devices. Instead, they are surface-mounted to the printed-circuit-boards (PCBs) of the wireless communication devices and are manufactured separately from the integrated circuits. This separate manufacturing increases the cost, time, and complexity of fabrication.

### SUMMARY

Deep trench (DT) MEMS resonators are high aspect-ratio resonators that address many of the problems associated with FBARs and SAW resonators. A DT MEMS resonator generally includes a periodic array of unit cells, each of which includes a single DT formed in a semiconductor substrate (e.g., silicon). Each DT is filled with a material (e.g., poly-silicon) whose acoustic impedance is different than that of the substrate. The filled DT is used as both an electrical capacitor and a mechanical structure at the same time, making it an elegant design that reduces footprint and fabrication complexity.

The periodic array of unit cells in a DT MEMS resonator forms an acoustic Bragg reflector (ABR) structure whose reflection band is determined by the unit cell width, the trench width, and the acoustic impedance mismatch between the substrate and the trench filling. PolySi-filled trenches in a Si substrate can form a “weak reflector” that traps the standing wave inside the ABR layer instead of scattering the standing wave off into the substrate. By trapping the standing wave, the weak reflector enhances the DT MEMS resonator's quality factor, Q.

DT MEMS resonators offer many advantages over QBARs and SAW resonators. For example, DT MEMS resonators may be solidly embedded and do not require a release step or extensive packaging. The frequency of a DT MEMS resonator can be defined lithographically, with the cavity and reflectors fabricated in the same mask and self-aligned. And a DT MEMS device can function as a mechanical reflector and/or an electrical capacitor. For more information on DT MEMS devices, see, e.g., U.S. Pat. No. 9,041,492 and International Application No. PCT/US2015/035116, which are incorporated herein by reference in their entireties.

Nevertheless, the inventors have recently recognized several potential areas for improving the weak reflector system formed by Si-polySi in a more conventional DT MEMS resonator. First, using a single DT per unit cell limits the range of mechanical bandgap sizes due to the small acoustic impedance mismatch between Si and polySi. Limits on the range of mechanical bandgap sizes limit the range of frequencies over which the DT MEMS resonator transmits and/or reflects acoustic waves. Filling the DTs with another conductive material, such as metal, increases attenuation and reduces the Q of the mechanical mode. But, depositing metal uniformly on the trench sidewalls and filling the trenches can be a challenge in terms of fabrication. Non-uniform deposition and filling may make the mechanical bandgap more difficult to control, which in turn could reduce the production yield of a device with metal-filled trenches. Second, a weak reflector system may need more layers (and hence a larger footprint) than a strong reflector system to generate a high Q. Third, the size of the resonant cavity can be difficult to determine during layout design, which can lead to low fabrication yield. Fourth, fabrication defects, such as voids and surface dents, can affect the weak mechanical bandgap from Si-poly Si, which can also lead to low fabrication yield.

Embodiments of the dual-trench deep-trench (DTDT) MEMS resonators disclosed herein address the issues of fabrication yield and sensitivity to fabrication non-idealities associated with single-trench DT MEMS resonators. A DTDT MEMS resonator takes advantage of a weak mechanical bandgap structure, yet has a mechanical bandgap size controllable through fabrication to reduce susceptibility to manufacturing defects, etc.

An example DTDT MEMS resonator may include a substrate that defines a plurality of unit cells arranged in a first direction. Each unit cell in the plurality of unit cells comprises at least one first material disposed in a first trench defined in the substrate and at least one second material disposed in a second trench defined in the substrate. The first and second materials each have an acoustic impedance that is different than the acoustic impedance of the substrate. In operation, the first material senses, conducts, and/or generates an acoustic wave. In some cases, the length of at least one unit cell in the plurality of unit cells is selected based on a desired frequency of the acoustic wave. The spacing between a center of the first trench and a center of the second trench in a first unit cell in the plurality of unit cells may be about half of a length of the first unit cell.

The first material in a first unit cell in the plurality of unit cells can be electrically connected to a source of an electrical signal. In this, the second material in the first unit cell is electrically isolated from the source of the electrical signal.

The first material may comprise a conductive material and a dielectric layer disposed to form a capacitor. The first material may also comprise a piezoelectric material.

The second material may be selected based on a desired frequency of the acoustic wave. The acoustic impedance of the second material may be lower than the acoustic impedance of the substrate. In some cases, the second material comprises at least two materials selected to define a resonance frequency of at least a portion of the plurality of unit cells. In these cases, one of these two materials comprises an oxide of silicon whose thickness is selected to define the mechanical bandgap.

In operation, an electrical signal may be applied to the first material of the example DTDT MEMS resonator so as to generate an acoustic wave. At least a portion of the acoustic wave is coupled to a second unit cell in the plurality of unit cells via the second material disposed in the second trench of the first unit cell. The electrical signal may be applied to at least a subset of the plurality of unit cells. At least a portion of the acoustic wave may be sensed via the second material in the second trench of a second unit cell in the plurality of unit cells. For instance, some or all of the acoustic wave may be sensed via the second materials in the second trenches in each of a subset of the plurality of unit cells. The acoustic wave may also be at least partially reflected towards the first unit cell, e.g., by a reflector formed by other unit cells.

Embodiments of the present technology also include methods of making DTDT MEMS resonators. An example method includes forming a plurality of unit cells in or on a substrate, with each unit cell in the plurality of unit cells comprising a first material disposed within a first trench and a second material disposed in a second trench. Forming the unit cells may be accomplished by: forming a plurality of trenches in the substrate; depositing the first material within the plurality of trenches; removing the first material from every other trench in the plurality of trenches; and depositing the second material in the every other trench in the plurality of trenches. In some cases, all or substantially all of the first material is removed from every other trench before the second material is deposited; in other cases, only a portion of the first material is removed from every other trench before the second material is deposited.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1A shows an exemplary DTDT unit cell structure with a first DT filled with transducer conductive material and a second DT fully filled with oxide material functioning as an acoustic reflector.

FIG. 1B shows an exemplary DTDT unit cell structure with a first DT filled with transducer material and a second DT partially filled with oxide material functioning as an acoustic reflector.

FIG. 2A shows an unreleased DTDT MEMS resonator.

FIG. 2B shows an unreleased DTDT MEMS resonator with a resonant cavity between graded index (GRIN) regions and reflector arrays.

FIG. 3A shows a fabrication process for an unreleased resonator that includes DTDT unit cells with a fully filled oxide trenches like the one shown in FIG. 1A.

FIG. 3B shows a fabrication process for an unreleased resonator that includes DTDT unit cells with a partially filled oxide trenches like the one shown in FIG. 1B.

FIGS. 4A-4D shows plots of absolute acoustic reflectivity versus frequency for resonators with 5, 10, and 30 unit DTDT cells with oxide trenches that are filled with 0.1 μm thick oxide (FIG. 4A), 0.15 μm thick oxide (FIG. 4B), 0.25 μm thick oxide (FIG. 4C), and fully filled with oxide. (FIG. 4D).

FIGS. 4E and 4F are plots of extracted peak reflectivity versus number of cells and extracted peak frequency versus number of cells, respectively, for unreleased resonators with DTDT unit cells with oxide trenches that are filled with 0.1 μm thick oxide, 0.15 μm thick oxide, 0.25 μm thick oxide, and fully filled with oxide.

FIG. 5A is a plot of simulated wave vector-frequency (k-ω) dispersion curves for a DTDT unit cell with a fully filled acoustic reflector trench. The inset at top-left shows the DTDT unit cell used in the simulation.

FIG. 5B shows the waveguide eigenmodes at k=π/L for the simulations of FIG. 5A.

FIG. 5C is a plot of simulated wave vector-frequency (k-ω) dispersion curves for a DTDT unit cell with a partially filled acoustic reflector trench. The inset at top-left shows the DTDT unit cell used in the simulation.

FIG. 5D shows the waveguide eigenmodes at k=π/L for the simulations of FIG. 5C.

FIG. 6A shows a DTDT-based resonator with a sensing region sandwiched between drive regions, GRIN regions, and reflectors.

FIG. 6B shows a modeshape at a frequency of 1.309 GHz as supported by the DTDT-based resonator of FIG. 6A with fully filled oxide trenches and a quality factor Q=760.

FIG. 6C shows a modeshape at a frequency of 1.309 GHz as supported by the DTDT-based resonator of FIG. 6A with partially filled oxide trenches and a quality factor Q=1100.

FIG. 6D is a plot of the frequency response of the resonator structures shown in FIGS. 6B and 6C, where the data points are from a simulation and the curves are from data fitting to the data points.

FIG. 7A shows a DTDT unreleased resonator structure (top) that includes a transducer array sandwiched between reflector arrays and a close-up of the transducer array (bottom).

FIG. 7B shows a DTDT unreleased resonator structure (top) that includes a transducer array sandwiched between GRIN regions and reflector arrays and a close-up of the transducer array (bottom).

FIG. 7C is a plot of the frequency response of the resonator structures shown in FIGS. 7A and 7B, whether the data points are from a simulation and the curves are fits to the data points.

FIG. 8 is a plot of frequency response curves for DTDT resonator structures with 24-, 60-, and 90-unit cell transduction arrays.

FIG. 9A is a plot of simulated wave vector-frequency (k-ω) dispersion curves for a DTDT unit cell with a fully filled acoustic reflector trench and a void in the polySi. The inset shows the DTDT unit cell used in the simulation.

FIG. 9B shows the waveguide eigenmodes at k=π/L for the simulations of FIG. 9A.

FIG. 9C is a plot of simulated wave vector-frequency (k-ω) dispersion curves for a DTDT unit cell with a fully filled acoustic reflector trench and a void in the oxide. The inset shows the DTDT unit cell used in the simulation.

FIG. 9D shows the waveguide eigenmodes at k=π/L for the simulations of FIG. 9C.

FIG. 10A shows the simulated modeshape of a DTDT resonator with voids inside the polySi DT where the plotted wave pattern is σₓₓ.

FIG. 10B shows the simulated modeshape of a DTDT resonator with voids inside the SiO₂ DT where the plotted wave pattern is σₓₓ.

FIG. 10C shows the frequency response curves of resonator structures with voids inside the polySi DT, with voids inside the SiO₂ DT, and without any voids in the DT.

### DETAILED DESCRIPTION

A dual-trench deep-trench (DTDT) resonator has a unit cell that includes two deep trenches (DTs): a first DT for electrical transduction and a second DT that modulates the mechanical bandgap size, which in turn determines the DTDT resonator's resonance frequency and the band over which the DTDT resonator transmits and/or reflects acoustic waves. The second DT may have a size and filling selected to define a mechanical bandgap that is small enough to provide low reflectivity and trap acoustic waves, yet large enough not to be affected by process variations or to cause cavity matching problems. For example, by partially filling the second DT of a DT unit cell with oxide, the mechanical bandgap can be tuned to just the right size to support a high Q mode, and at the same time be large enough not to be eliminated due to process variations. The use of two DTs per unit cell enables a greater range of mechanical bandgap sizes without breaking the translational symmetry that leads to high quality factors.

An array-based DTDT solid-state resonator design is also relatively robust against unexpected process variations. Periodic defects, such as voids inside either DT or surface scattering voids generated from material deposition, are well-handled by a DTDT solid-state resonator. The reason is that because such defects shift the waveguide modes in both the transducer region and the reflector region together, preserving the resonance mode. The resonance frequency may still be shifted after the introduction of periodic defects, but no over-design is necessary during the layout design stage to protect against such variations. This saves layout space and increases the fabrication yield.

Unit Cells for DTDT MEMS Resonators

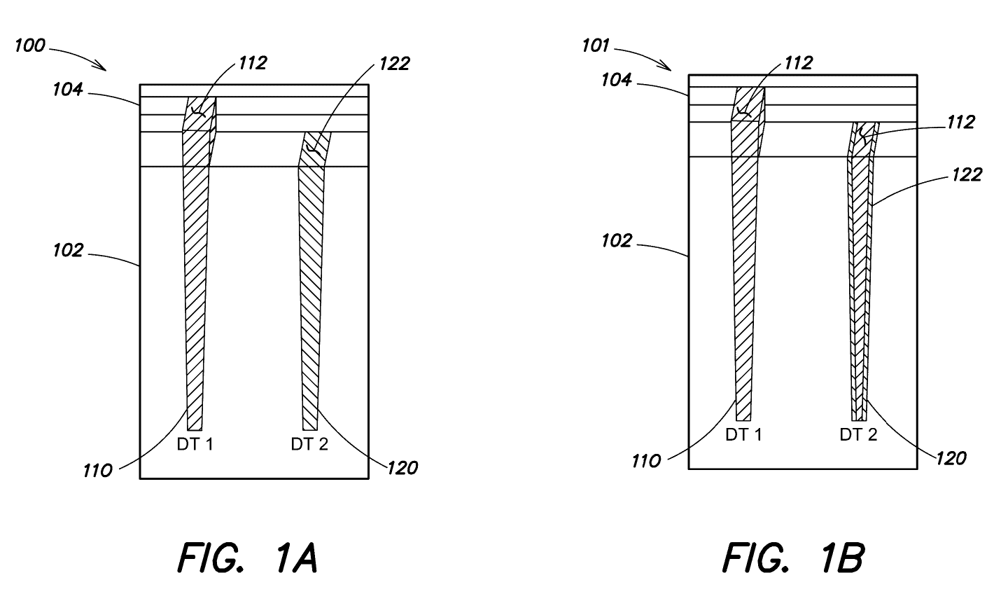

FIGS. 1A and 1B show DTDT unit cells for use in DTDT MEMS resonators. More specifically, FIG. 1A shows a unit cell 100 that includes a first DT 110 and a second DT 120 formed in a substrate 102 (e.g., a silicon substrate). The first DT 110 is filled with a first material 112—here, a conductive material, such as polySi—and the second DT 120 is filled with a second material 122—here, an insulating material, such as SiO₂. The first material 112 and the second material 122 have acoustic impedances that are different (e.g., lower) than the acoustic impedance of the substrate 102 and optionally of each other as well. The acoustic impedances of the first material 112 and the second material 122 may be different too. The substrate 102 and the insulating material 122 are covered with an insulating layer 104 (e.g., more SiO₂). The first material 112 is exposed through holes in the insulating layer 104 to form electrical connections with other components/devices.

In operation, the first material 112 in the first DT 110 functions as an electrical capacitor or a piezoelectric transducer, depending on the composition of the first material 112. If functioning as an electrical capacitor, the first material 112 may include a conductive material deposited within a thin layer of insulating material. If functioning as a piezoelectric transducer, the first material 112 may include a piezoelectric or piezoresistive material deposited within a thin layer of insulating material. For more information, see International Application No. PCT/US2015/035116, which is incorporated herein by reference in its entirety.

The insulating material 122 in the second DT 120, which is electrically isolated from the first DT 110 by the substrate 102 and the insulating layer 104, functions as an acoustic reflector. In other words, the second DT 120 and the insulating material 122 in the second DT help to determine the frequency and width of the resonance of the unit cell 100. Depending on the unit cell's function, the frequency and width of the unit cell's resonance may be selected to transmit or reflect radiation at one or more acoustic wavelengths.

FIG. 1B shows a unit cell 101 in which the second DT 120 is partially filled with insulating material 122 (e.g., SiO₂) and partially filled with conductive material 112 (e.g., more polySi). The insulating material 122 is deposited along the boundary of the second DT 120 to a desired thickness, leaving the remaining gap to be filled by the conductive material 112 during deposition of conductive material 112 in the first DT 110. The thickness of the insulating material 122 deposited in the second DT 122 can be controlled during device fabrication to achieve a desired resonance frequency and resonance width. This tunability can be achieved with any suitable set of materials, including but not limited to Si, polySi, and SiO₂.

The resonance frequency of the unit cell 100 depends on the pitch L of the unit cell 100, the width w_{DT} of the second DT 120, and, in the unit cell 101 shown in FIG. 1B, the thickness tₒₓ of the oxide deposited in the second DT 120, among other things. (The width of the first DT 110 and the distance between the first DT 110 and second DT 120 may also affect the resonance frequency.) The trench width w_{DT} may be fixed due to constraints on filling the trench during fabrication. The pitch size L can be used to position the center frequency of the mechanical bandgap, and the oxide thickness tₒₓ can be used to tune the width of the mechanical bandgap. Other parameters may affect the unit cell's resonance frequency, including the distance between the first DT 110 and second DT 120; in some cases, this distance may be about L/2, L/3, L/4, etc., where L is the pitch of the unit cell 100.

The pitch L of the unit cell 100 can be expressed in terms of the acoustic wavelength λ within the unit cell 100. Depending on the unit cell's function, the pitch may be one-quarter (λ/4) to one-half (λ/2) of the acoustic wavelength λ, depending on the unit cell's function (e.g., transduction or sensing). In physical dimensions, the acoustic path length of the unit cell 100 can range from about 100 nm to about 100 μm (e.g., 200 nm, 300 nm, 400 nm, 500 nm, 600 nm, 700 nm, 800 nm, 900 nm, 1μm, 5μm, 10 μm, 15 μm, 20 μm, 30 μm, 40 μm, 50 μm, 60 μm, 70 μm, 80 μm, 90 μm). Depending on the unit cell's desired acoustic and mechanical properties, the thickness of each DT 110, 120 may range from about 1 nm to about 100 μm (e.g., 5 nm, 10 nm, 15 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 200 nm, 300 nm, 400 nm, 500 nm, 600 nm, 700 nm, 800 nm, 900 nm, 1μm, 5μm, 10 μm, 15 μm, 20 μm, 30 μm, 40 μm, 50 μm, 60 μm, 70 μm, 80 μm, 90 μm).

Example DTDT MEMS Resonators

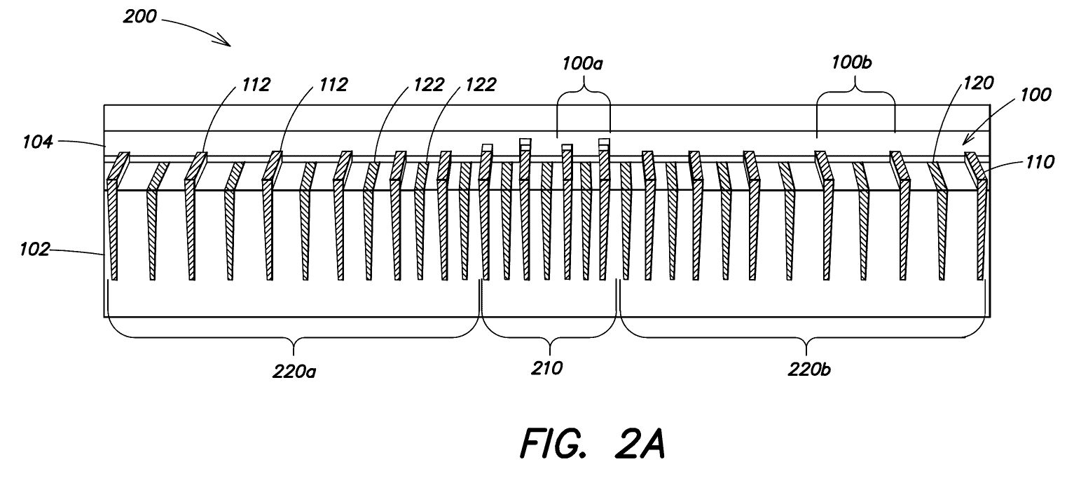

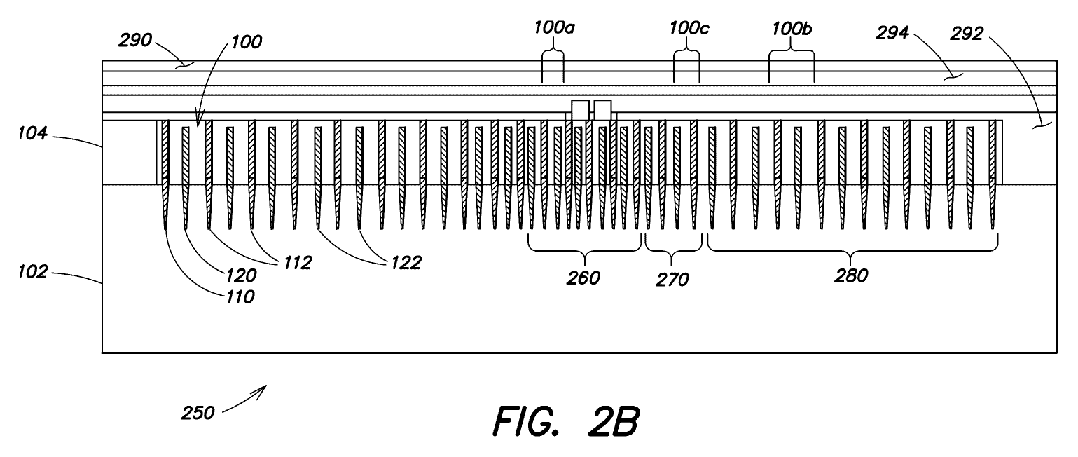

FIGS. 2A and 2B illustrate DTDT MEMS resonators that include unit cells 100 with second DTs 120 fully filled with second (insulating) material 122 as shown in FIG. 1A. Similar DTDT MEMS resonators could be fabricated with unit cells whose second DTs hold heterogeneous fillings, e.g., as shown in FIG. 1B. A DTDT MEMS resonator may also include a mixture of unit cells with second DTs containing homogeneous and heterogeneous filings. In both examples, polySi filled trenches and SiO₂ filled trenches are distributed in the transducer zone and reflector zones, including in the center portions, which are used for signal transduction. This maintains translational symmetry, and therefore provides much higher Q.

FIG. 2A shows a DTDT MEMS resonator 200 that includes unit cells 100 with different pitches arranged to form a transducer array 210 sandwiched between a left reflector array 220a and a right reflector array 220b (collectively, reflector arrays 220). As explained above, each unit cell 100 includes a first DT 110 at least partially filled with a first material 112 (e.g., polySi) and a second DT 120 filled with a second material 122 (e.g., SiO₂). An insulating layer 104 covers the exposed portion of the substrate, the second DTs 120, the and second material 122. The insulating layer 104 may also cover some or all of the first DTs 110 and first material 112 in the reflector arrays 220. The first material 112 in the transducer array 210 pokes through the insulating layer 104 to form electrical connections with a signal source and/or a signal detector, depending on whether the transducer array 210 generates or detects acoustic waves propagating within the DTDT MEMS resonator 200.

The first DT 110 and second DT 120 are formed in a substrate 102 (e.g., silicon) whose acoustic impedance is different (e.g., higher) than that of the first material 112 and the second material 122. These acoustic impedance differences, together with the dimensions of the unit cells 100, determine the acoustic properties of the DTDT MEMS resonator 100. In this case, the transducer array 210 includes unit cells 100a whose dimensions—including pitch L, trench widths, and trench locations—are selected to resonate at one or more acoustic frequencies. The reflector arrays 220, also called acoustic Bragg reflectors (ABRs), include unit cells 100b whose dimensions are selected to provide an acoustic path length of about λ/4, where λ is the wavelength of the acoustic wave(s).

In operation, the reflector arrays 220 confine the resonant acoustic wave(s) to a cavity defined by the transducer array 210. In some cases, the transducer array 210 may generate the acoustic wave(s), e.g., via piezoelectric or electrostatic transduction in response to an electrical signal from a signal source in electrical communication with the transducer array 210 via the exposed first material 112. In other cases, the transducer array 210 may sense the acoustic wave(s), e.g., via piezoelectric or electrostatic transduction.

FIG. 2B shows a DTDT MEMS resonator 250 with unit cells 100 of different pitches L arranged to form a resonant cavity 260 sandwiched between a pair of symmetric graded index (GRIN) sections 270, which in turn are sandwiched between a pair of symmetric ABRs 280. Again, each unit cell 100 includes a first DT 110 at least partially filled with a first material 112 (e.g., polySi) and a second DT 120 filled with a second material 122 (e.g., SiO₂). And each unit cell 100 has dimensions, including a pitches L, selected based on its function. For example, the unit cells 100a in the resonant cavity 260 have dimensions selected to support propagation of acoustic waves within a given frequency range. The unit cells 100c in the ABRs 280 have dimensions selected to reflect some or all of the acoustic waves resonating in the resonant cavity 260 (e.g., acoustic path lengths equal to λ/4).

FIG. 2B shows that the GRIN sections 270 have unit cells 100c whose pitches and/or other dimensions vary as a function of position from the pitch of a resonator unit cell 100a to the pitch of an ABR unit cell 100b. In this case, the acoustic path lengths of the unit cells 100c in the GRIN sections 270 increase with distance from the resonant cavity 260. Put differently, the periods of the unit cells 100c are chirped to produce a smooth change in acoustic impedance similar to the smooth change of refractive index in an optical waveguide with a graded refractive index. Thus, each GRIN section 270 can be thought of as a chirped acoustic grating. The acoustic path length may vary linearly, quadratically, etc. as a function of position.

The DTDT MEMS resonator 250 also includes electrodes, shown in FIG. 2B as a signal electrode 292 and a ground electrode 294, that can be used to sense and/or generate acoustic waves within the resonant cavity 260. These electrodes may include portions of conductive traces that interconnect the DTDT MEMS resonator 260 to other components of an Integrated Circuit (IC) that reside on the same substrate 102. As discussed above, the first DTs 110 and first material 112 in the resonator unit cells 100a can be configured to act as electrostatic, piezoelectric, or piezoresistive transducers. Applying a voltage to these transducers via the signal electrode 292 and the ground electrode 294 creates an acoustic wave within the resonant cavity 260. Similarly, an acoustic wave propagating within the resonant cavity 260 generates a change in potential, e.g., via the piezoelectric effect, that can be measured across the signal electrode 292 and the ground electrode 294.

In addition, the DTDT MEMS resonator 250 has an insulating layer 104 that covers the exposed portion of the substrate, the second DTs 120, and the second material 122. Depending on the electrode configuration, the insulating layer 104 may also cover some or all of the first DTs 110 and first material 112 in the reflector arrays 220. The first material 112 in the transducer array 210 pokes through the insulating layer 104 to form electrical connections with a signal source and/or a signal detector, depending on whether the transducer array 210 generates or detects acoustic waves propagating within the DTDT MEMS resonator 200.

A DTDT MEMS resonator can include other layers or regions. For instance, it may include several resonant cavities, one or more of which act as sensors and one or more of which act as signal generators. These resonant cavities can be coupled together by acoustic Bragg grating couplers (ABGCs), which are arrays of unit cells dimensioned to transmit acoustic waves at selected frequencies. Typically, the acoustic path length of an ABGC unit cell is about equal to the acoustic wavelength, λ. Likewise, the number of unit cells in each region in a DTDT MEMS resonator (transducer array/resonant cavity, GRIN, ABR, or ABGC) may be selected based on the desired performance characteristics of the DTDT MEMS resonator. For example, ABGCs and ABRs with more layers tend to have higher finesses. And a DTDT MEMS resonator may include additional surface layers, including a protective coating, an acoustic reflector, and/or additional electromechanical interfaces for signal transduction and/or sensing with one or more external sources.

Fabrication of DTDT MEMS Resonators

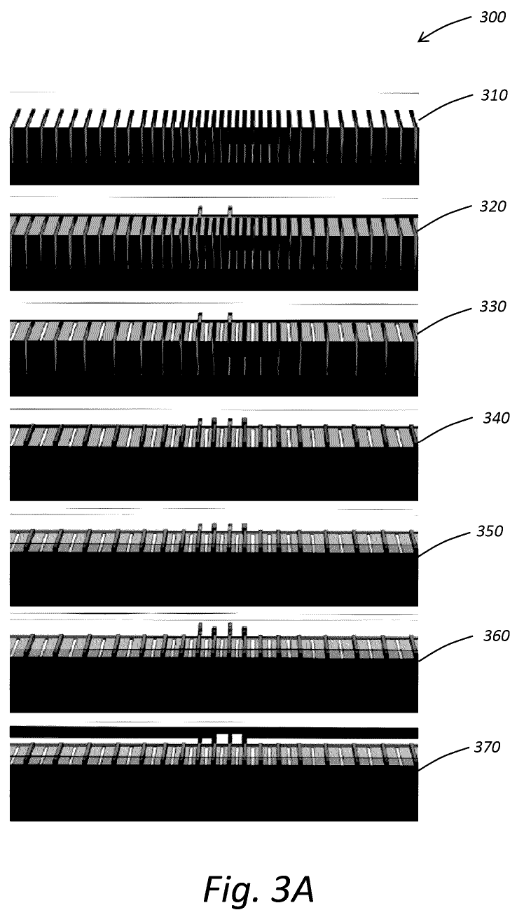

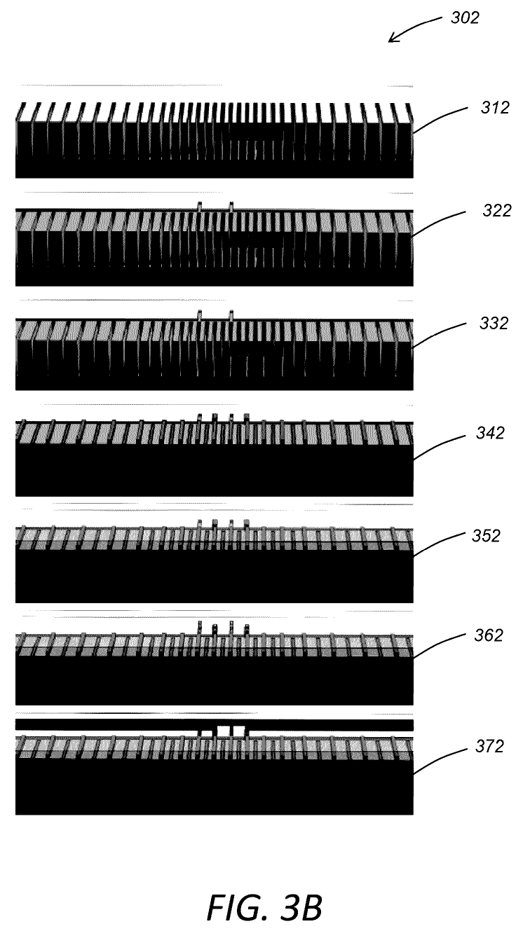

A DTDT MEMS resonator can be fabricated according to the processes described below and shown in FIGS. 3A and 3B. Those of ordinary skill in the art will readily understand that these processes and the process parameters can be modified as desired and that a DTDT MEMS resonator may be fabricated according to other processes.

Generally, a process for fabricating a DTDT MEMS resonator starts with deposition of 1 μm plasma-enhanced chemical vapor deposition (PECVD) SiO₂ onto a fresh low resistivity bulk n type Si wafer. Afterwards, the PECVD oxide is patterned using a hard mask to form 0.8 μm wide deep-trench (DT) arrays using stepper photo-lithography. The hard oxide mask is re-patterned into field oxide layer I (FOX I) to reduce capacitance from the subsequent electrical paths. It is patterned through a photoresist mask and wet 7:1 buffered HF (BHF) etch. This mask is also used as the ion implantation mask afterwards. The Si wafer is ion implanted with phosphorous twice, each time at tilt angle of 8°. The tilt reduces or avoids the channeling effect, and achieves implantation on the trench sidewall as well. CVD oxide is grown, then pattered into an alternating geometry through photo-lithography and wet etch in BHF. The oxide deposition can either fully fill the trench or just partially fill the trenches as desired. Whether the oxide filled trenches are fully filled or partially filled does not necessarily affect the process flow significantly.

After RCA clean, the trenches are lined with 10 nm SiO₂ and filled with n type doped polySi. The polySi grows uniformly on top surfaces and sidewalls, filling all the trenches, including the ones that are partially filled with SiO₂ if the oxide DTs are indeed partially filled. The polySi is lined with a thin layer of Al to reduce RC delay, and these layers are subsequently patterned into electrical paths for the top electrode of the DT capacitor. This step also opens the contact area for substrate grounding. The solid state structure is capped with a 500 nm field oxide II (FOX II) to reduce scattering of elastic wave from the top free surface and to isolate the electrical signal between metal layers. The FOX II is patterned for metal contacts to the transducer DTs and substrate. Finally, a Ti—Al metal layer is sputtered, patterned by Cl₂/BCl₃ RIE, and sintered at 450° C. in H₂/N₂ gases.

FIG. 3A illustrates a fabrication process 300 for making a DTDT MEMS resonator with fully filled acoustic reflector trenches. In step 310, DTs are etched into a Si substrate using oxide hard mask. An oxide hard mask is patterned into a window for ion implantation into the substrate (step 320). After ion implantation, oxide is deposited uniformly and patterned by wet etch (step 330). After depositing a thin dielectric layer, n type polySi is deposited and patterned to fill inside the remaining DTs (step 340). In step 350, a field oxide layer is deposited on top of such structure for electrical isolation and acoustic confinement. In step 360, electrical contact holes are etched through field oxide. In step 370, a Ti—Al metallization stack is deposited and patterned.

FIG. 3B illustrates a fabrication process 302 for a DTDT MEMS resonator with partially filled acoustic reflector trenches. In step 312, DTs are etched into Si substrate using oxide hard mask. In step 322, an oxide hard mask is patterned into a window for ion implantation into the substrate. After ion implantation, oxide is deposited uniformly (step 332). This partially filled oxide is covered by photoresist and patterned into the alternating geometry. After depositing thin dielectric layer, n type polySi is deposited and patterned to fill inside the remaining DTs (step 342). In step 352, a field oxide layer is deposited on top of the structure for electrical isolation and acoustic confinement. In step 362, electrical contact holes are etched through field oxide. In step 372, a Ti—Al metallization stack is deposited and patterned.

TABLE 1
Design Parameter Values for a DTDT Resonator

| | |
|---|---|
| Frequency (f) | 1.3 GHz |
| Trench depth (h_{DT}) | 8 μm |
| Trench width | (W_{DT}) 0.8 μm |
| Device width | (w) 60 μm, 100 μm |
| FOX I thickness (t_{FOX1}) | 0.6 μm |
| FOX II thickness (t_{FOX2}) | 0.5 μm |
| Dielectric thickness (t_{diel}) | 10 nm |
| polySi thickness (t_{poly}) | 0.8 μm |
| Ti thickness (t_{Ti}) | 0.1 μm |
| Al thickness (t_{Al}) | 1 μm |
| Fill SiO₂ thickness | 0.15 μm |
| Transducer DT pitch (Lₜᵣₐₙₛ) | 3.4 μm |
| Reflector DT pitch (L_{ref}) | variable, e.g. 3.8 μm |

TABLE 2 (below) provides a detailed description of a process for fabricating a DT MEMS resonator, including process parameters and tools. It also includes the additional steps used to fabricate a DTDT MEMS resonator.

TABLE 2
DT/DTDT MEMS Resonator Fabrication Process

| Section | Steps | Detailed Process Parameters | Tool |
|---|---|---|---|
| Mask 1: | Spin photoresist | SPR-700 at 2000 rpm, about 1.4 μm | coater6 |
| alignment marks | (PR) | thick | |
| | Exposure, develop | soft bake 30 s at 95° C., exposure dose | i-stepper |
| | and bake | 160 ms, post exposure bake 30 s at 115° | |
| | | C., develop in “MF-CD-26” for 2 min, | |
| | | then hard bake 45 s at 120° C. | |
| | Etch Si | Etch rate: 4 nm/s, CH A oxide | AME5000 |
| | | breakthrough first, then etch 100 s in | |
| | | CH B | |
| | Strip PR | 3 min | asher-ICL |
| | Piranha clean | 10 min | premetal- |
| | | | Piranha |
| Mask 2: Deep | RCA clean | | rca-ICL |
| Trench etch | Deposit PECVD | 1 um thick, recipe name “CHA-oxide- | DCVD |
| | oxide as hard mask | 1 um” | |
| | Spin PR | SPR-700 at 2000 rpm, about 1.4 μm | coater6 |
| | | thick | |
| | Exposure, develop | soft bake 30 s at 95° C., exposure dose | i-stepper |
| | and bake | 150 ms, post exposure bake 30 s at 115° | |
| | | C., develop in “MF-CD-26” for 2 min, | |
| | | then hard bake 45 s at 120° C. | |
| | Etch SiO₂ | Etch rate: 3 nm/s, etch 325 s | AME5000 |
| | Strip PR | 3 min | asher-ICL |
| | DRIE etch in Si | 5.5 min DRIE to get 7.5 μm deep DT | sts2 |
| | Hard mask recess | wet etch in 7:1 BHF for 50 s | Greenflo |
| | One-step Si etch | 2 min using the one-step slow etch rate | sts2 |
| | | recipe | |
| Mask 3: pattern | Spin PR | SPR-700 at 2000 rpm, about 1.4 μm | coater6 |
| ion implantation | | thick | |
| mask | Exposure, develop | dose 160 ms | i-stepper |
| | Hard bake | 30 min oven hard bake in the 120° C. | postbake |
| | | oven in TRL | |
| | Wet etch SiO₂ | Etch rate: 250-300 nm/min, etch 3 min | Greenflo |
| | Strip PR | 3 min | asher-ICL |
| | Piranha clean | 10 min | Greenflo |
| | RCA clean | | rca-TRL |
| DRIE polymer | Wet oxidation | 20 min dry oxidation, 15 min wet | A2- |
| removal | | oxidation, then 20 min dry oxidation | WetOxBond |
| | Wet etch | 1 min wet etch in 14:1 BHF to remove | Greenflo |
| | | the thermal oxide | |
| Ion implantation | RCA clean | | rca-TRL |
| | Dry oxidation | 1 h dry oxidation at 850° C. to get 10 | A2- |
| | | nm thermal oxide. This is used as the | WetOxBond |
| | | implantation barrier layer | |
| | Ion implantation | outsource at Innovion. Energy-50 keV, | |
| | | Dose-4e15 cm⁻², tilt-7°, rotation-0° and | |
| | | 180° | |
| | Double piranha | 10 min & 10 min | Greenflo |
| | clean | | |
| | Oxide strip | 45 s 14:1 BHF dip to remove | Greenflo |
| | | implantation oxide | |
| Mask 4: trench | RCA clean | | rca-TRL |
| oxide fill (used | Oxide trench fill | 20 min LPCVD oxide deposition | 6C-LTO |
| for DTDT MEMS | Spin image reversal | AZ5214 at 2000 rpm, about 1 μm thick | coater |
| resonator) | PR | | |
| | Exposure | exposure dose 160 ms | i-stepper |
| | Post exposure bake | 120° C. for 1.5 min on hotplate | postbake |
| | Flood exposure and | 1 min flood exposure, then develop in | EV1 |
| | develop | AZ422 for 5 min with untrasonic, | |
| | | followed by a second round of 1 min | |
| | | flood and 10 min development with | |
| | | ultrasonic to clear resist in the trenches | |
| | Hardbake | 30 min | postbake |
| | Etch SiO₂ | Etch rate: 470 nm/min, wet etch 30 s in | Greenflo |
| | | 7:1 BHF | |
| | Strip PR | 3 min | asher-ICL |
| Mask 5: poly-Si | Piranha clean | 10 min | Greenflo |
| fill and etch | RCA clean | | rca-TRL |
| | Dry oxidation | 1 h dry oxidation at 850° C. to get 10 | A2- |
| | | nm thermal oxide. This is used as | WetOxBond |
| | | capacitor dielectrics | |
| | Poly-Si deposition | two consequtive depositions, each run | 6A-nPoly |
| | | takes 100 min to get a total thickness of | |
| | | 800 nm | |
| | Anneal | at 950° C. for 30 min. This is used to | B3-DryOx |
| | | activate both the poly-Si dopants and | |
| | | the implantation dopants | |
| | A1 deposition | deposit 750 nm of A1 | Endura |
| | Spin PR | SPR-700 at 1200 rpm, about 1.8 μm | coater6 |
| | | thick | |
| | Exposure, develop | dose 170 ms | i-stepper |
| | and bake | | |
| | Etch A1 and poly-Si | etch 300 s | rainbow |
| | Strip PR | 4 min, extra time is for cleaning | asher-ICL |
| Mask 6: field | Deposit PECVD | 500 nm thick | concept1 |
| oxide patterning | oxide | | |
| | Spin pr | spr-700 at 2000 rpm, about 1.4 μm | coater6 |
| | | thick | |
| | Exposure, develop | dose 160 ms | i-stepper |
| | and bake | | |
| | Dry etch SiO₂ | etch rate: 200 nm/min, etch 2 min | lam590-ICL |
| | Strip pr | 3 min | asher-ICL |
| Mask 7: | HF dip | 14:1 BHF, dip 15 s | Greenflo |
| Metallization | Deposit metal | 100 nm of Ti and 1 μm of A1 | Endura |
| | Spin pr | spr-700 at 2000 rpm, about 1.4 μm | coater6 |
| | | thick | |
| | Exposure, develop | dose 140 ms | i-stepper |
| | and bake | | |
| | Dry etch the metal | etch 135 s | rainbow |
| | stack | | |
| | Strip pr | 3 min | asher-ICL |
| | Sinter | 450° C. for 30 min with forming gas | A3-Sinter |
| | | (N₂/H₂) | |

Simulated Performance of DTDT MEMS Resonators

Reflectivity of DTDT Acoustic Bragg Reflectors (ABRs)

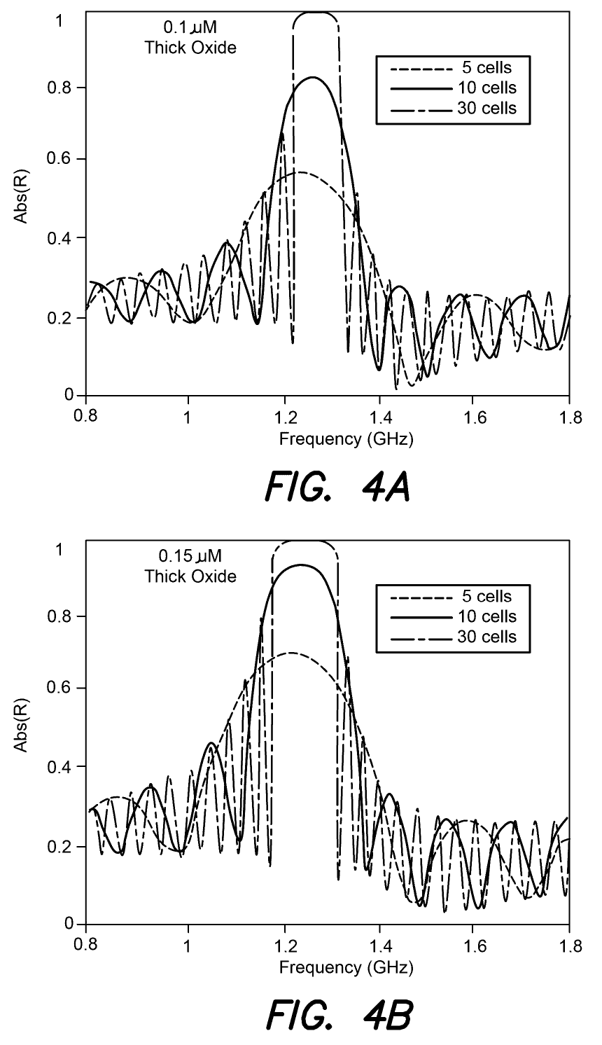

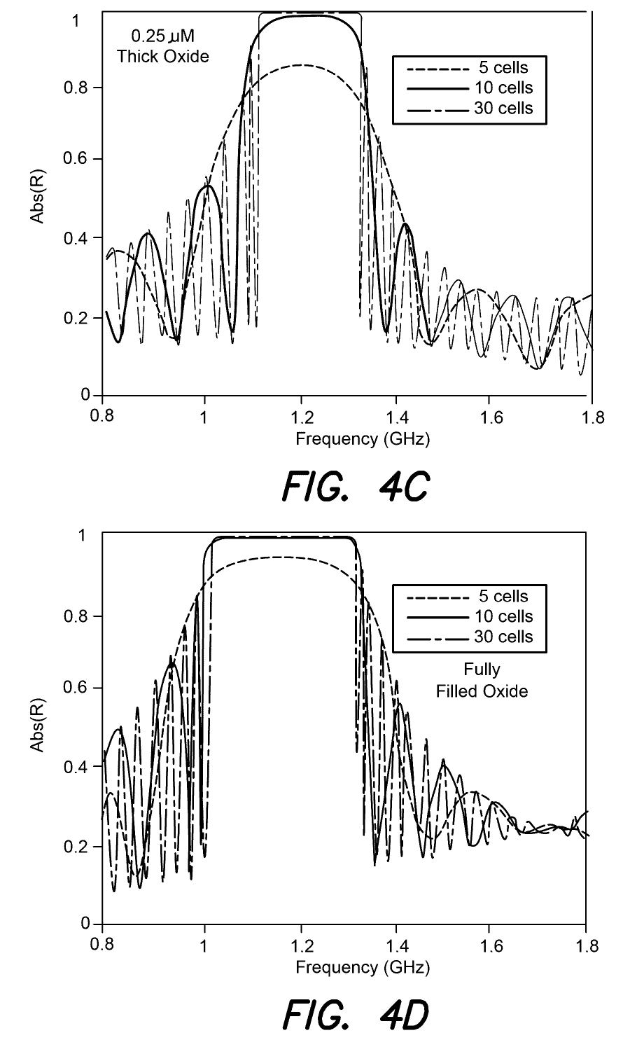

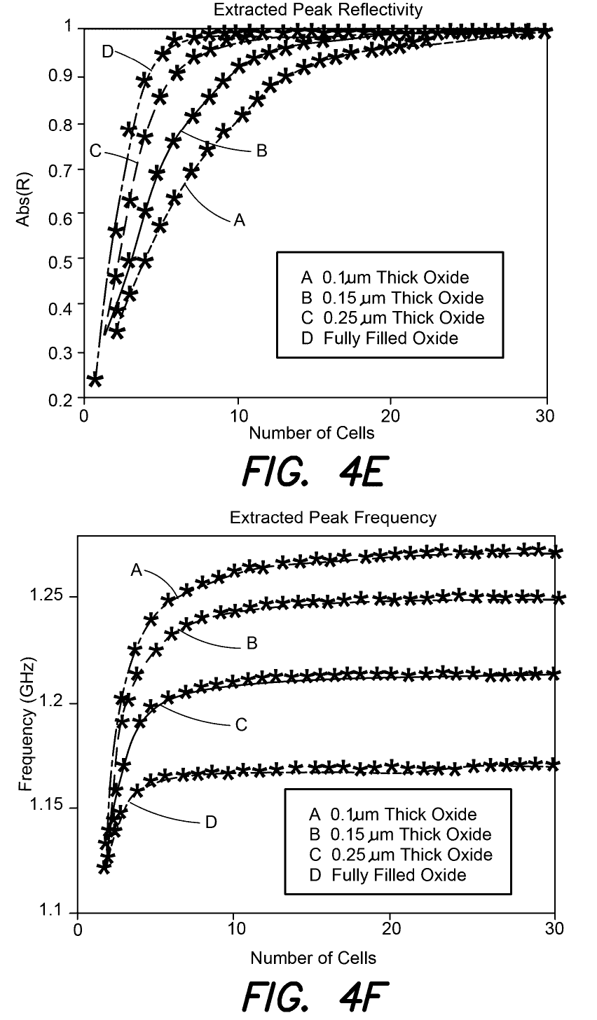

FIGS. 4A-4F shows the reflectivity of various DTDT structures simulated using numerical methods. FIGS. 4A, 4B, 4C, and 4D show the reflectivity for oxide thicknesses of 0.1 μm, 0.15 μm, 0.25 μm, and fully filled, respectively in the acoustic reflector DTs. Each plot displays the absolute reflectivity as a function of frequency for 5 cells, 10 cells, and 30 cells. FIGS. 4A-4D show that the mechanical bandgap size (the length of the segment where the reflectivity is close to 1) increases as the deposited oxide thickness increases, with the maximum mechanical bandgap ratio being around 30% when the trench is fully filled with SiO₂. By adjusting the oxide thickness, this mechanical bandgap size can be tuned smaller. Since 30% is already a big mechanical bandgap ratio, this provides enough range for mechanical bandgap tuning.

Generally, the high reflectivity band shifts in frequency as the number of cells increases. Such peak reflectivity and center frequencies can be extracted as well, plotted in FIGS. 4E and 4F, respectively. As seen from FIGS. 4E and 4F, the mechanical bandgap center frequency becomes stable when the number of cells increases beyond 10. And a wider mechanical bandgap causes the reflectivity to converge to 1 faster.

Dispersion Relations for DTDT Unit Cells

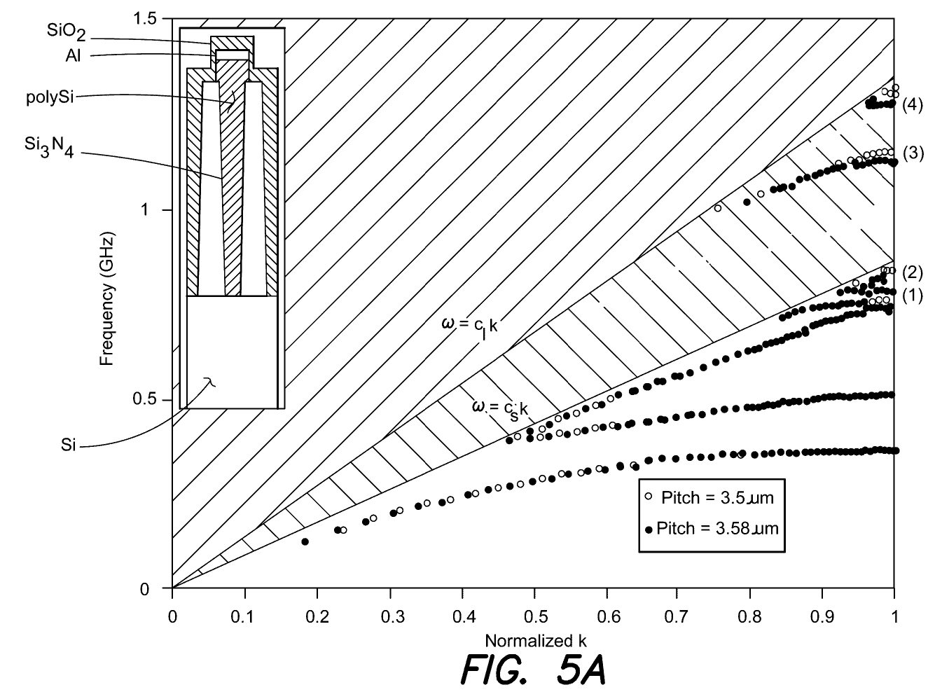

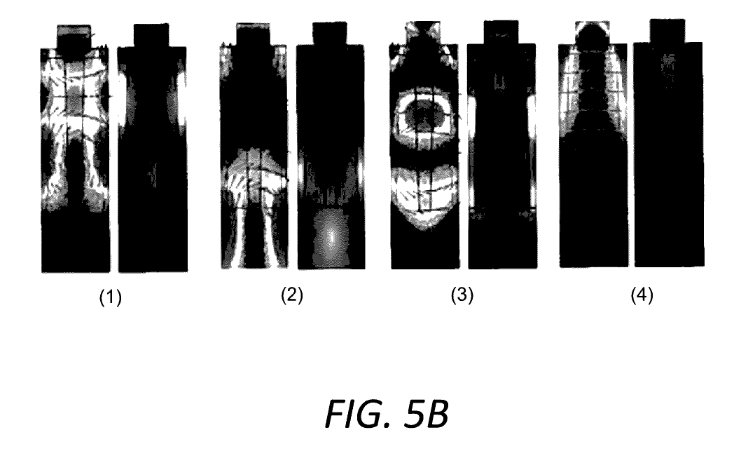

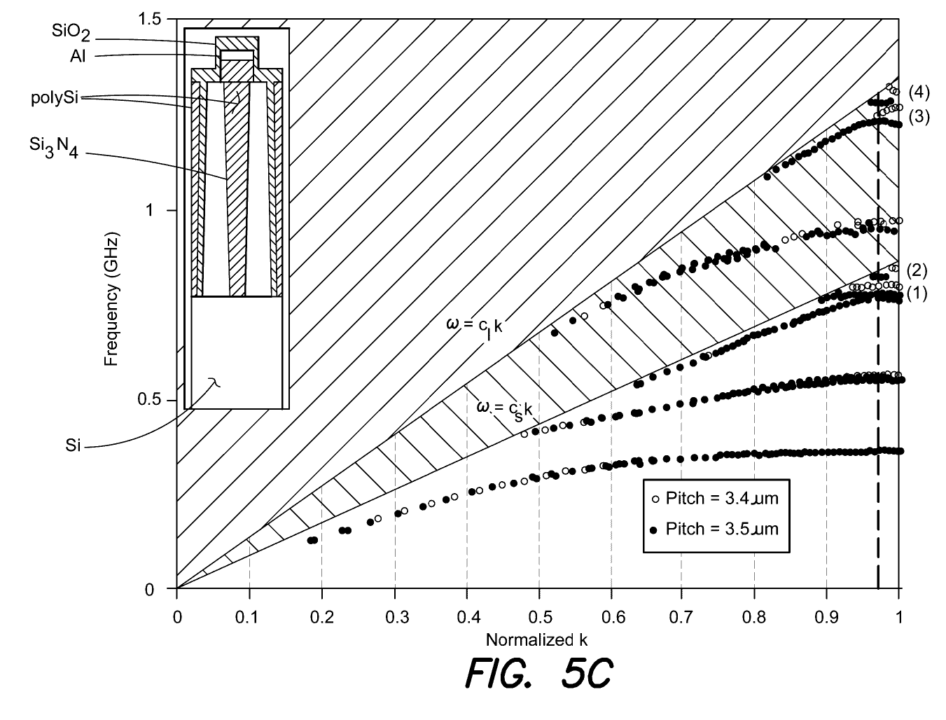

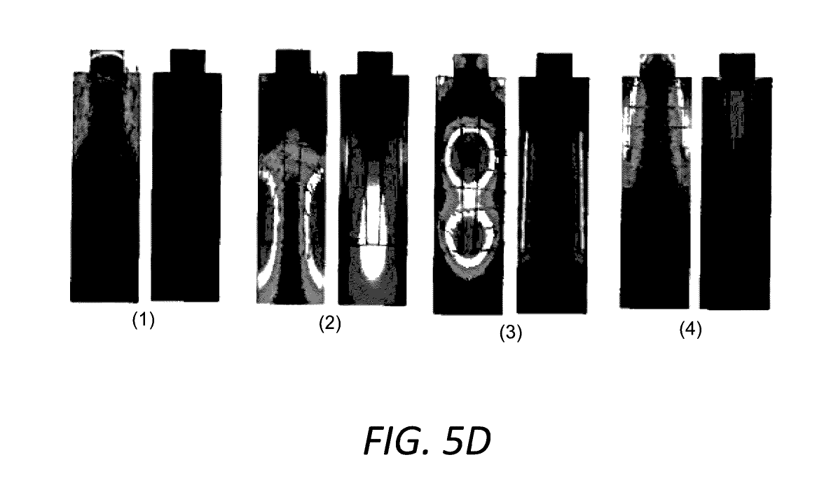

FIGS. 5A and 5B show the results of a dispersion analysis of a DTDT unit cell with a fully filled acoustic reflector trench, whereas FIGS. 5C and 5D illustrate a dispersion relation study based on a DTDT unit cell with an acoustic reflector trench in which the SiO₂ thickness on the trench sidewall is 0.15 μm. The DTDT unit cells for the dispersion analyses are shown in the insets of FIGS. 5A and 5C. Bloch boundary conditions are applied between the left boundary and the right boundary, and the bottom Si is set to 10 times the thickness of the top DT ABR layer (not shown in the inset). To represent the inherent mirror symmetry in each unit cell, the mechanical bandgap tuning trench is cut in half, leaving one half on each side. This does not affect the analysis result since the Bloch boundary condition is applied.

FIGS. 5A and 5C show kω dispersion curves for the DTDT unit cell, in which the k axis is normalized to kₒ=π/L and the frequency axis has units of GHz. Dots indicate the eigenmodes, the lightly shaded zone marks the area between the shear wave sound cone (ω=cₛk) and the longitudinal wave sound cone (ω=cₗk), and the dark shaded zone marks the longitudinal wave sound cone (ω=cₛk).

FIGS. 5B and 5D show the waveguide eigenmodes at k=π/L in FIGS. 5A and 5C, respectively. The modes map to the numbers marked along the right-hand axes shown in FIGS. 5A and 5C. Modes (1) and (2) are shear dominant modes, and modes (3) and (4) are bulk longitudinal modes. The displacement rainbow plot on the left and the energy heat plot on the right show that mode (4) has the cleanest longitudinal mode and is therefore the target for the DTDT resonator design in each case.

In each dispersion analysis the DTDT pitch size is the only study variable, while all the other parameters including trench width, depth, thickness of each materials, etc., are kept constant. In FIG. 5A, the lighter dots represent eigenmodes at a pitch size of 3.4 μm and the darker dots represent eigenmodes at a pitch size of 3.5 μm. (The center-to-center spacing of the DTs within each unit cell is half the pitch, i.e., for the unit cells with a pitch of 3.4 μm, the spacing between the DTs in the unit cell is 1.7 μm.) The kₒ used to normalize both sets of curves is chosen to be kₒ=π/(3.4 μm). As a result, to put both plots on the same scale of k, the dispersion curves for pitch size of 3.4 μm reaches only kₙₒᵣₘ=3.4/3.5=0.97 (blue dashed line in FIG. 5A) after k scaling, and the curves beyond that are symmetric mirror images.

Overlaying the dispersion curves for the different DTDT pitch sizes shows how the modes shift after perturbing the pitch size. If, for example, the pitch size of the transducer DTs is 3.4 μm, and the pitch size of the reflector DTs is 3.5 μm, the wave can propagate when operating on the lighter curves, but this same mode becomes evanescent after reaching the reflector since it is not on the darker curves. Even when using array transduction to operate at k/kₒ=1, k spans a certain width around the targeted value because the array size is not infinite. Therefore, to construct high Q resonators, such modes should be as far away from the sound cone as possible, and the two modes should be separated as far as possible at both the targeted k value and its vicinity. For example, mode (4) of both pitch sizes is well separated over the entire plotted range of k, and the mode is almost pure longitudinal, which couples to the driving forces. It may operate closer to the sound cone than the other modes, but this sound cone coupling effect can be reduced by using larger transduction arrays (which leads to purer k value).

FIGS. 5C and 5D can be analyzed in a similar way. Here since the longitudinal mechanical bandgap is smaller, mode (3) and mode (4) are closer to each other (the separation of these two branches can be viewed as the mechanical bandgap in such context). But if the transducer DTs are at a pitch size of 3.4 μm, and the reflector DTs are at pitch size 3.5 μm, the mode can propagate on one waveguide but may be isolated on the other, forming a solid state resonator under array transduction.

Resonator Eigenmodes and Q Enhancement Approaches

Resonator Eigenmodes

The full frequency response of the entire structure and many resonator properties, including Q, can be extracted from a finite element analysis model of the DTDT MEMS resonator. For example, a MATLAB optimizer can be used to control a COMSOL finite element solver at each iteration of a finite element analysis to find a solution that generates a desired Q. The optimizing program can search the transducer array pitch size (Lₜᵣₐₙₛ) and the reflector array pitch size (L_{ref}), while the other parameters are kept constant. This numerical simulation procedure can be applied on DTDT resonator structures with fully filled or partially filled mechanical bandgap tuning trenches.

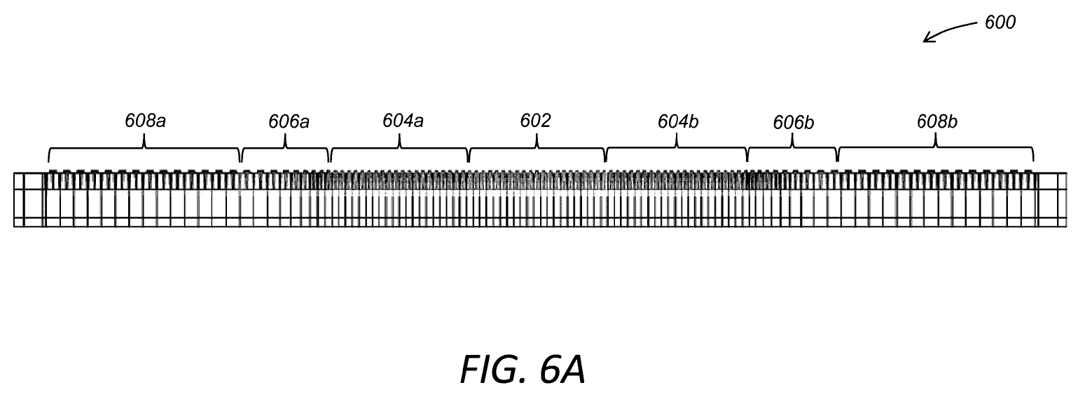

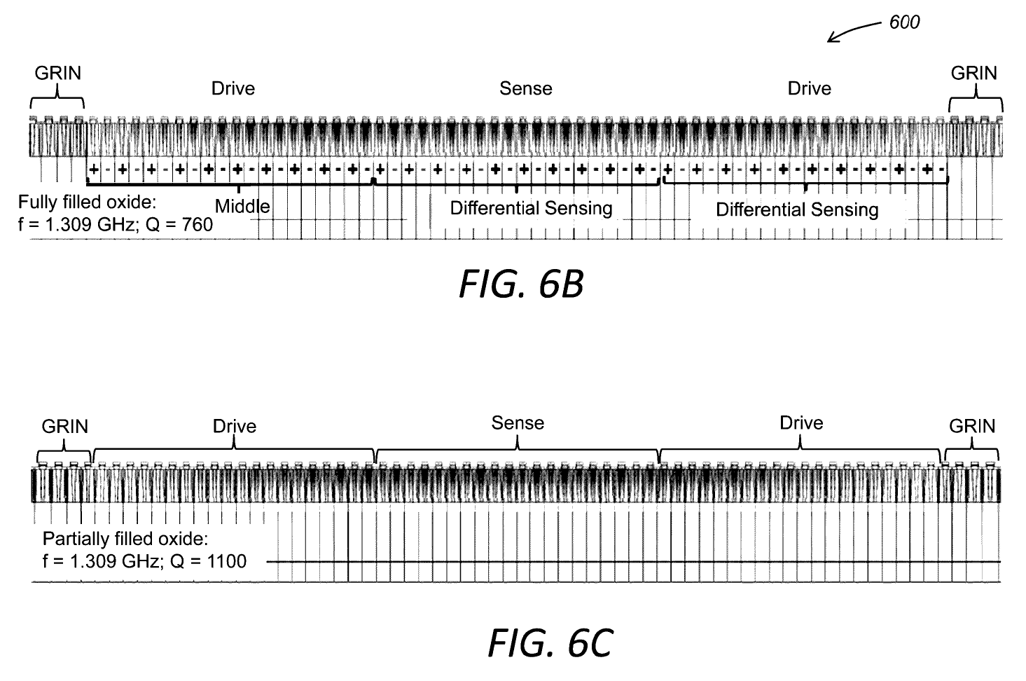

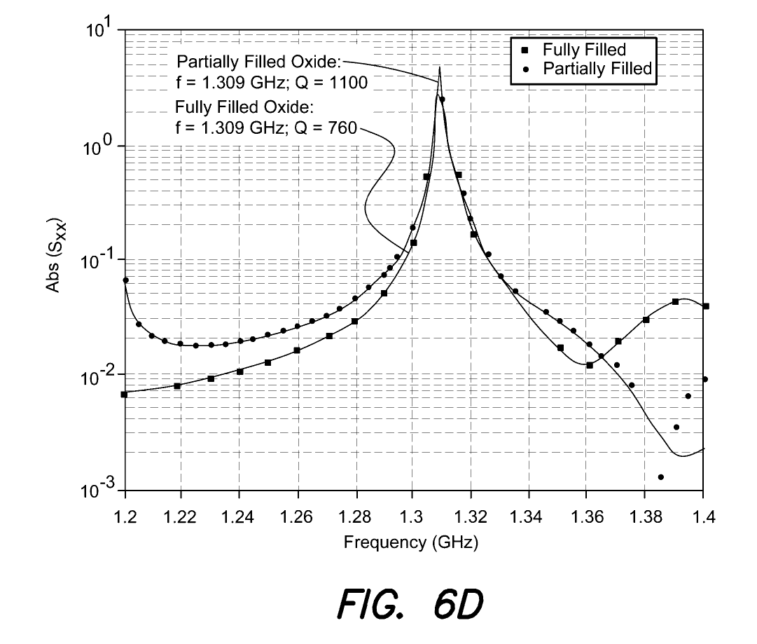

FIGS. 6A-6D illustrate a comparison of the optimized eigenmodes from fully filled and partially filled DTDT resonators obtained using an optimizer to control a finite element solver. FIG. 6A shows a schematic of a fully filled DTDT resonator structure 600. As introduced previously, the structure 600 is based on matching two DTDT waveguides with different pitch sizes using “graded index” (GRIN) sections 606a and 608b as transitions region to keep better translational symmetry. The structure 600 includes a transducer array that is divided into three segments, in which the first and third segments are used as driving arrays 604a and 604b, and the second segment is used as a sensing array 602. The structure 600 also includes reflectors 608a and 608b at either end.

FIGS. 6B and 6C show the geometries used in a COMSOL simulation to extract resonance modeshapes at a frequency of 1.309 GHz for DTDT-based resonators with fully filled and partially filled oxide trenches, respectively, and quality factors of Q=760 and Q=1100, respectively. The function of each region in each DTDT resonator is marked on top of the simulation geometry schematic. Each driving array is driven alternately with positive voltage and negative voltage. Similarly, the sensing array is sensed differentially. This differential driving/sensing mechanism drives the structure efficiently, while reducing the electrical feedthrough floor. Shading indicates the peaks and troughs of the wave pattern of the σₓₓ distribution.

FIG. 6D is a plot of frequency responses of both structures. The dots in FIG. 6D are data points from simulation, and the curves are data fitting results using rational functions.

The simulations illustrated in FIGS. 6B-6D show that partially filled DTDT trench structures can provide almost twice the signal level and Q as fully filled DTDT trench structures. Without being bound by any particular theory, this result can be explained by the weaker mechanical bandgap of the partially filled dual trench structure. As discussed above, a weak mechanical bandgap reduces scattering and enhances Q, just as demonstrated by this comparison. And note that from the results in FIGS. 4A-4F, even this “weak mechanical bandgap” has a bandgap ratio of around 11%, which is far bigger than the 2% bandgap formed by Si-polySi. As a result, this medium-ranged bandgap has the Q-enhancement advantage of weak mechanical bandgap structures, but does not suffer from the mechanical bandgap narrow-down effect caused by non-periodic defects. These advantages are due to the mechanical bandgap tuning capability of the DTDT framework.

Further Q Enhancement Approaches

The quality factor Q of a solid state DTDT resonator can be enhanced by using a GRIN structure, longer transduction arrays, or both. The effect of the GRIN structure is to gradually transit the pitch size from the transducer pitch size to the reflector pitch size. This gradual transition reduces waves scattering at each reflection, and therefore improves Q.

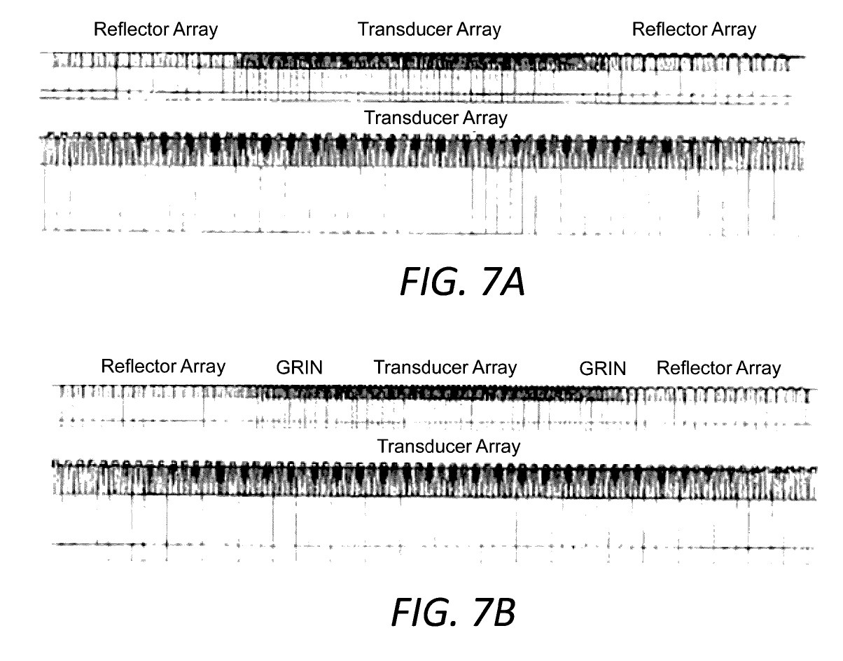

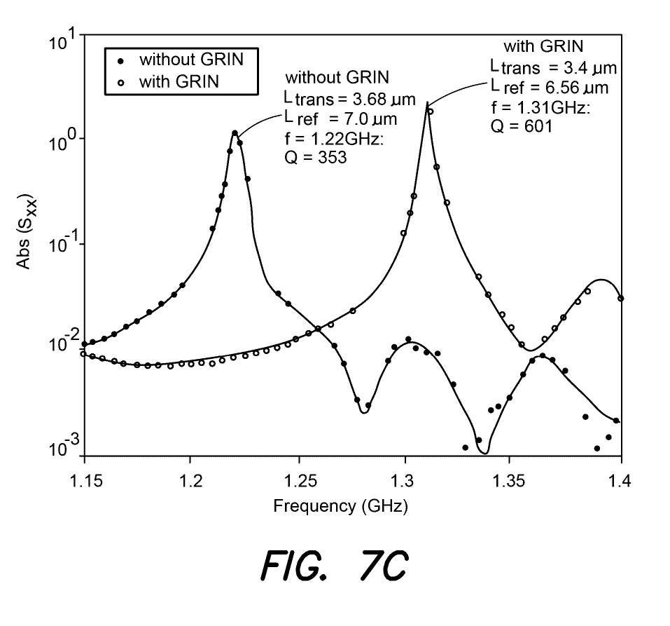

FIGS. 7A-7C show a comparison between a structure with GRIN regions and a structure without GRIN regions. FIG. 7A shows the base structure, which in this case is a DTDT structure in which the oxide trenches are fully filled. The plot on top of FIG. 7A shows the eigenmode at resonance in the full structure, and the plot at the bottom of FIG. 7A is a close up of the transducer array. The transducer array pitch size (Lₜᵣₐₙₛ) is 3.68 μm, the reflector array half pitch size (L_{ref}) is 7.0 μm, the resonance frequency is 1.22 GHz, and the quality factor is Q=353.

FIG. 7B shows the eigenmode at resonance for a DTDT resonator with GRIN regions and in which the oxide trenches are fully filled. Again, the plot on top shows the full view, and the plot at the bottom is a close up of the transducer array. The transducer array pitch size (Lₜᵣₐₙₛ) is 3.4 μm, the reflector array pitch size (L_{ref}) is 6.56 μm, the resonance frequency is 1.31 GHz, and the quality factor is Q=601.

FIG. 7C is a plot of the frequency response curves from the structures shown in FIGS. 7A and 7B. The dots are actual data points from simulation, and the curves are from data fitting. FIG. 7C shows that introducing GRIN regions nearly doubles the Q. Each curve is obtained from optimizing the corresponding structure, so it is a valid comparison that is based on equal footing. The modeshapes in FIGS. 7A and 7B show that abrupt transition of pitch size leads to more scattering into the substrate direction, which is represented by the heavier evanescent tail in the substrate Si (see, e.g., FIG. 7B, bottom).

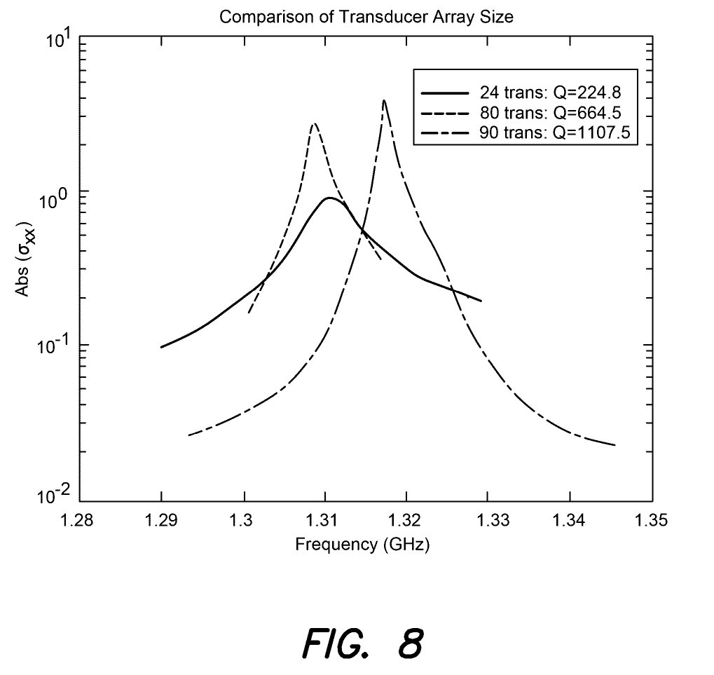

FIG. 8 is a plot of frequency response curves for DTDT resonators with fully filled oxide trenches and transducer arrays with 24 (Q=224.6), 60 (Q=684.5), and 90 transducers (Q=1107.5). Again, each curve is obtained from running the finite element optimization algorithm disclosed above. FIG. 8 shows that longer transducer arrays enhance Q. Without being bound by any particular theory, using longer transduction arrays can better localize the distribution of exited wave numbers in k space, keeping the excited modes away from the lossy sound cone, and increasing Q. This effect is deduced from analyzing the dispersion plot, and it can be further verified by running simulation on the full structure (e.g., as in FIG. 8).

Effects of Process Variations on DTDT Resonators

As discussed at above, solid state resonators based on weak mechanical bandgap structures are susceptible to fabrication variations. One example of an imperfect surface structure is the existence of non-periodic surface defects, which can cause scattering and distort the modeshape. For designs based on matching the cavity size to the reflector mechanical bandgap, such fabrication variations may shift the mechanical bandgap and cause the design match to fail. One common solution is to include a lot of over-designs in the layout, in order to hit a match even after the mechanical bandgap shifts. But this method wastes layout area and could still fail when unforeseen defects happen.

On the other hand, the array transduction design methodology disclosed herein is more robust to process variations. Assuming the process condition is uniform across the DTs in one device, the defects may depend largely, if not entirely, on the designed geometry. Since the designed geometry preserves translational symmetry as much as possible, including the details on the surface layers, any defects, if they exist at all, should have the same type of translational symmetry as well. One benefit of such periodic defects is that they should cause the transducer waveguide mode and the reflector waveguide mode to shift together, leaving the gap between these two modes almost unperturbed.

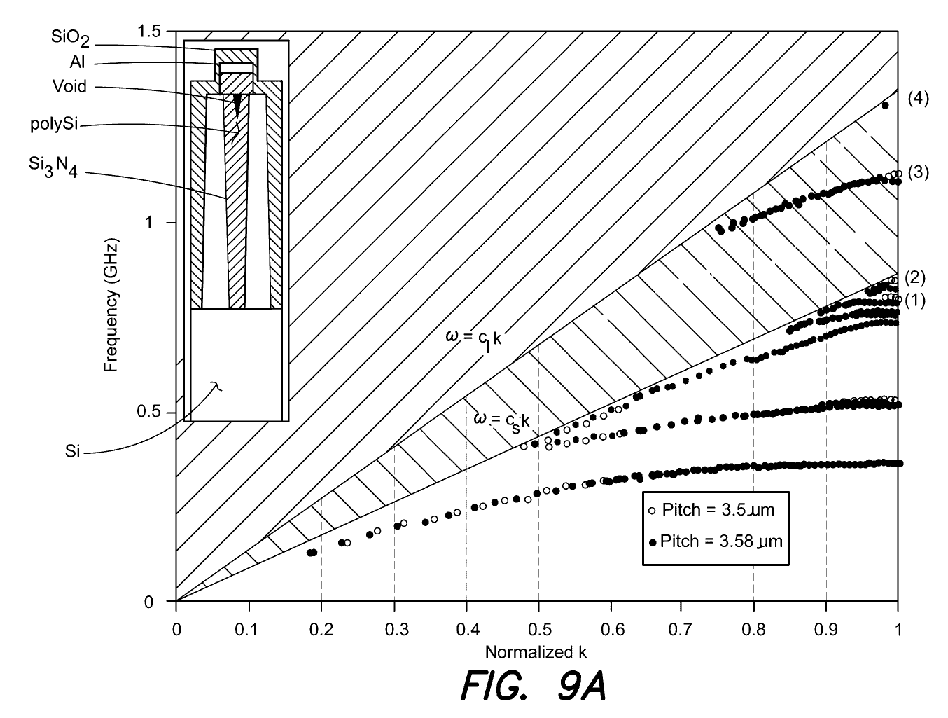

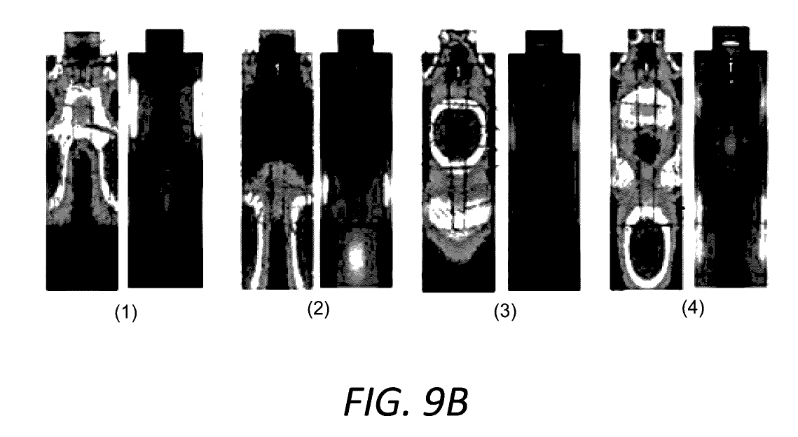

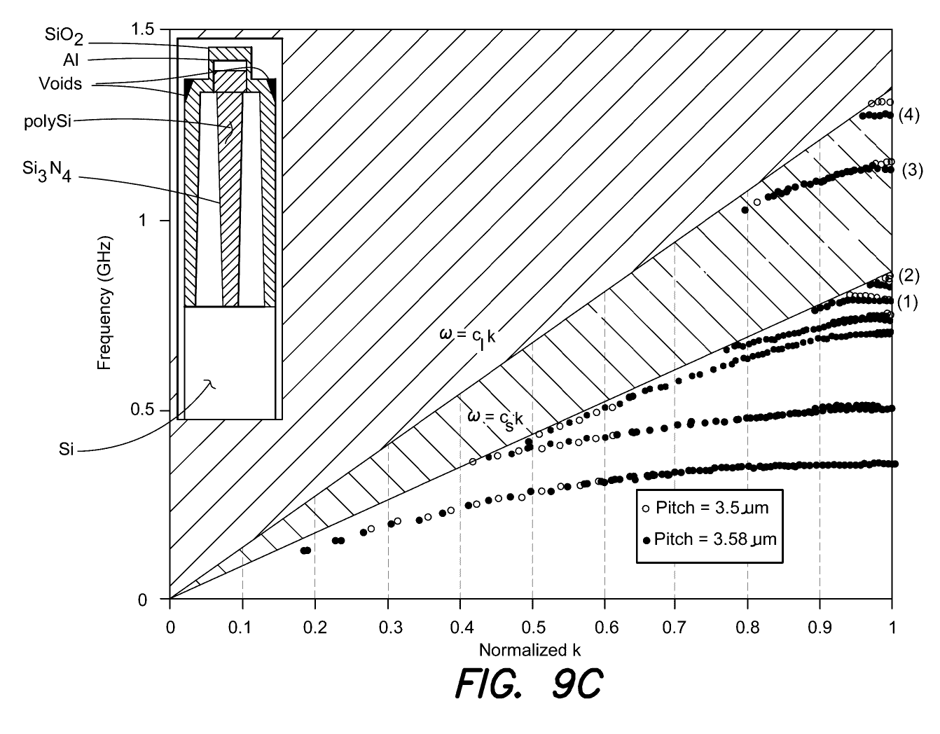

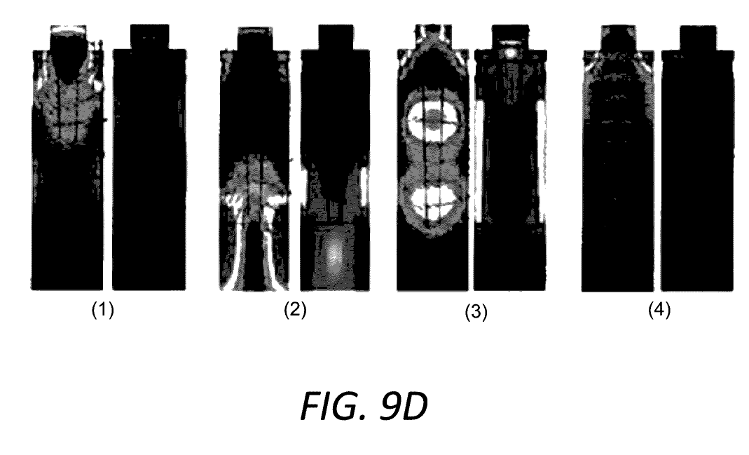

In comparison with FIGS. 5A-5D, which illustrate dispersion relations for DTDT resonators without any defects, FIGS. 9A-9D show dispersion curves for DTDT resonators with manufacturing defects. The designs themselves are shown in the insets of FIGS. 9A and 9C. In FIG. 9A, the void is in the polySi in the middle of the unit cell; in FIG. 9C, the void is in the SiO₂ at the edge of the unit cell.

FIGS. 9A and 9C show k-ω dispersion curves for the DTDT unit cell, in which the k axis is normalized to kₒ=π/L and the frequency axis has units of GHz. Bloch boundary conditions are applied between the left boundary and the right boundary, and the bottom Si is set to 10 times the thickness of the top DT ABR layer (not shown in the inset). Dots indicate the eigenmodes, the lightly shaded zone marks the area between the shear wave sound cone (ω=cₛk) and the longitudinal wave sound cone (ω=cₗk), and the dark shaded zone marks the longitudinal wave sound cone (ω=cₛk).

FIGS. 9B and 9D show the waveguide eigenmodes at k=π/L in FIGS. 9A and 9C, respectively. The modes map to the numbers marked along the right-hand axes shown in FIGS. 9A and 9C. Modes (1) and (2) are shear dominant modes, and modes (3) and (4) are bulk longitudinal modes. The displacement rainbow plot on the left and the energy heat plot on the right show that mode (4) has the cleanest longitudinal mode and is therefore the target for the DTDT resonator design in each case.

For a design based on two waveguides that are of slightly different pitch sizes, the goal of the mode design is usually to have a tiny offset between the two mode branches. As seen from FIGS. 9A-9D, however, voids in the fabricated DTDT resonators may cause large shifts in the dispersion curves, especially for the bulk modes. If the voids have the same spatial distribution as the DTs, the dispersion curves of both pitch sizes should shift together, largely preserving the size of the mode offset. As a result, even with the existence of defects, the exact same layout should still be able to generate working devices as long as the mode still exists outside of the sound cone. This robustness against process variations makes the layout design easier, meaning it does not require much, if any, over-design to compensate foreseeable or unforeseeable process variations because the devices can automatically adjust to such variations to some extent.

For such auto-adjustment to happen, the mode should still exist out of the sound cone. For example, in FIGS. 9A and 9B, where the void is in the polySi filled DT, mode (4) almost disappears. In FIGS. 9C and 9D, where the void is in the SiO₂ filled DT, mode (4) still exists, indicating that the device would still work with such a defect under the same layout dimensions.

Without being bound to any particular theory, the energy heat plot of mode (4) in FIGS. 9B and 9D suggests that the defect should be not located where the energy is concentrated for the mode is to be robust to defects. Placing a defect on a high energy density spot would eliminate such a mode, while placing a defect on a low energy density spot would not cause much perturbation. For example, FIG. 5B shows that the acoustic energy is concentrated in the top section of the polySi DT in mode (4). As a result, adding a void in polySi would introduce a lot of disturbance to such mode and push it outside of the sound cone. But FIG. 9D shows that adding a void in SiO₂ has little to no effect on the mode shape because mode (4) still is a pure longitudinal mode even with the voids.

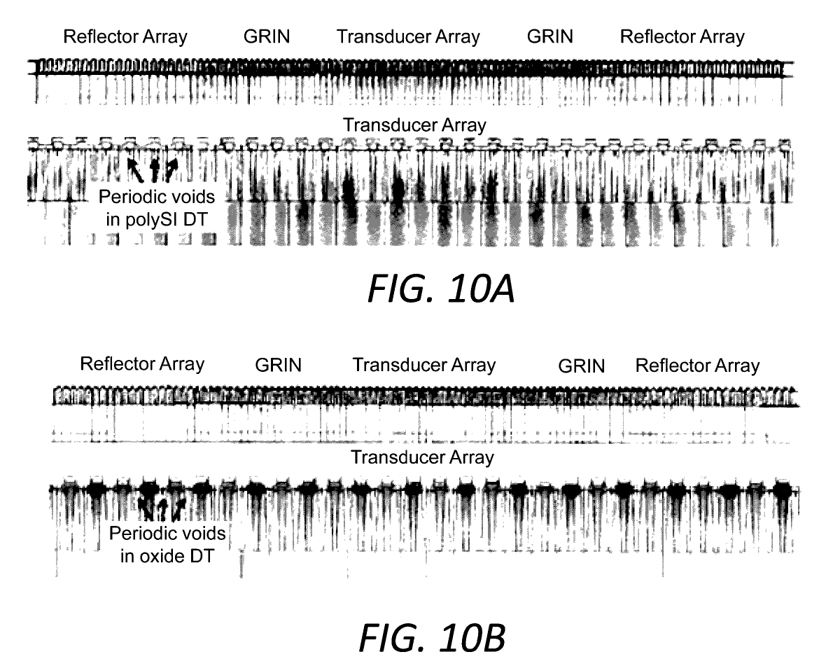

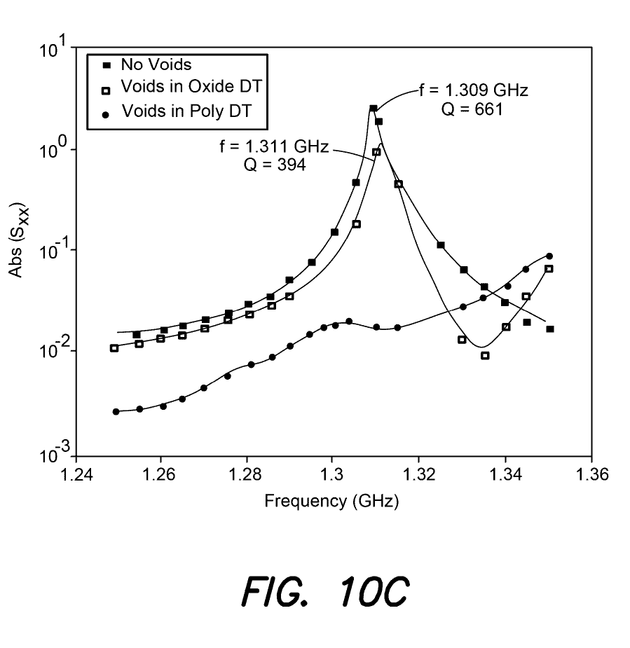

FIGS. 10A-10C illustrate a comparison of eigenmodes from DTDT resonators with GRIN regions and voids inside the polySi DT and the SiO₂ DT. FIG. 10A shows a COMSOL simulated modeshape of the DTDT resonator with voids inside the polySi DT. Again, the plotted wave pattern is σₓₓ. FIG. 10B shows a COMSOL simulated modeshape of the DTDT resonator with voids inside the SiO₂ DT. The plotted wave pattern is σₓₓ. And FIG. 17C shows frequency response curves for the structures in FIGS. 10A and 10B plotted against the response of the structure with no voids at all.

FIGS. 10A-10C verify the process variation conjectures based on the study of dispersion relations disclosed above. As seen from the figures in consistency with the dispersion mode shape study, the oxide-voided structure (FIG. 10A) shows uniform modeshape (middle curve in FIG. 10C). Its Q is reduced compared with the none-voided structure, but the mode still exists under exactly the same layout dimensions. However, the polySi-voided structure (FIG. 10B) does not have the same modeshape anymore, since the mode is scattered by the voids placed exactly on the spots where the energy is supposed to concentrate (bottom curve in FIG. 10C). And its frequency response also gives Q below 100.

Conclusion

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments can be implemented in any of numerous ways. For example, embodiments of designing and making the technology disclosed herein may be implemented using hardware, software or a combination thereof. When implemented in software, the software code can be executed on any suitable processor or collection of processors, whether provided in a single computer or distributed among multiple computers.

Further, it should be appreciated that a computer may be embodied in any of a number of forms, such as a rack-mounted computer, a desktop computer, a laptop computer, or a tablet computer. Additionally, a computer may be embedded in a device not generally regarded as a computer but with suitable processing capabilities, including a Personal Digital Assistant (PDA), a smart phone or any other suitable portable or fixed electronic device.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

The various methods or processes (e.g., of designing and making the technology disclosed above) outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the invention discussed above. The computer readable medium or media can be transportable, such that the program or programs stored thereon can be loaded onto one or more different computers or other processors to implement various aspects of the present invention as discussed above.

The terms “program” or “software” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present invention need not reside on a single computer or processor, but may be distributed in a modular fashion amongst a number of different computers or processors to implement various aspects of the present invention.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of” “only one of” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. An apparatus comprising:
a substrate defining a plurality of unit cells arranged in a first direction, each unit cell in the plurality of unit cells comprising:
at least one first material, disposed in a first trench defined in the substrate, to sense, conduct, and/or generate an acoustic wave, the at least one first material having an acoustic impedance different than an acoustic impedance of the substrate; and
at least one second material, disposed in a second trench defined in the substrate, to reflect and/or conduct at least a portion of the acoustic wave, the at least one second material having an acoustic impedance different than the acoustic impedance of the substrate.

2. The apparatus of claim 1, wherein a length of at least one unit cell in the plurality of unit cells is selected based on a desired frequency of the acoustic wave.

3. The apparatus of claim 1, wherein a spacing between a center of the first trench and a center of the second trench in a first unit cell in the plurality of unit cells is about half of a length of the first unit cell.

4. The apparatus of claim 1, wherein the at least one first material in a first unit cell in the plurality of unit cells is electrically connected to a source of an electrical signal.

5. The apparatus of claim 4, wherein the at least one second material in the first unit cell is electrically isolated from the source of the electrical signal.

6. The apparatus of claim 1, wherein the at least one first material comprises a conductive material and a dielectric layer disposed to form a capacitor.

7. The apparatus of claim 1, wherein the at least one first material comprises a piezoelectric material.

8. The apparatus of claim 1, wherein the at least one second material is selected based on a desired frequency of the acoustic wave.

9. The apparatus of claim 1, wherein the acoustic impedance of the at least one second material is lower than the acoustic impedance of the substrate.

10. The apparatus of claim 1, wherein the at least one respective second material comprises at least two materials selected to define a resonance frequency of at least a portion of the plurality of unit cells.

11. The apparatus of claim 10, wherein a first material of the at least two materials comprises an oxide of silicon having a thickness selected to define the mechanical bandgap.

12. A method of propagating an acoustic wave through a plurality of unit cells formed in or on a substrate, each unit cell in the plurality of unit cells comprising a first material disposed within a first trench and a second material disposed in a second trench, the method comprising:
applying an electrical signal to the first material disposed in the first trench of a first unit cell in the plurality of unit cells so as to generate the acoustic wave; and
coupling at least a portion of the acoustic wave to a second unit cell in the plurality of unit cells via the second material disposed in the second trench of the first unit cell.

13. The method of claim 12, wherein applying an electrical signal to the at least one first material comprises:
applying the electrical signal to the respective first materials in at least a subset of the plurality of unit cells.

14. The method of claim 12, further comprising:
sensing the at least a portion of the acoustic wave via the second material in the second trench of a second unit cell in the plurality of unit cells.

15. The method of claim 12, wherein sensing comprises:
sensing the at least a portion of the acoustic wave via the second materials in the second trenches in each of a subset of the plurality of unit cells.

16. The method of claim 12, further comprising:
reflecting at least a portion of the acoustic wave towards the first unit cell.

17. A method of making an apparatus, the method comprising:
forming a plurality of unit cells in or on a substrate, each unit cell in the plurality of unit cells comprising a first material disposed within a first trench and a second material disposed in a second trench.

18. The method of claim 17, wherein forming the plurality of unit cells comprises:
forming a plurality of trenches in the substrate;
depositing the first material within the plurality of trenches;
removing the first material from every other trench in the plurality of trenches; and
depositing the second material in the every other trench in the plurality of trenches.

19. The method of claim 18, wherein removing the first material from the every other trench in the plurality of trenches comprises removing substantially all of the first material.

20. The method of claim 18, wherein removing the first material from the every other trench in the plurality of trenches comprises removing a portion of the first material.
